(19) United States
(12) Patent Application Publication
(10) Pub. No.: US 2013/0171446 A1
(43) Pub. Date: Jul. 4, 2013

(54) COATED ARTICLE AND METHOD FOR MAKING SAME

(71) Applicants: QI-JIAN DU, ShenZhen City (CN); CHWAN-HWA CHIANG, Shindian (TW)

(72) Inventors: QI-JIAN DU, ShenZhen City (CN); CHWAN-HWA CHIANG, Shindian (TW)

(73) Assignees: FIH (HONG KONG) LIMITED, Kowloon (HK); SHENZHEN FUTAIHONG PRECISION INDUSTRY CO., LTD., ShenZhen City (CN)

(21) Appl. No.: 13/451,075

(22) Filed: Apr. 19, 2012

(30) Foreign Application Priority Data
Dec. 29, 2011 (CN) 201110450661.0

(51) Int. Cl. B32B 15/082; B05D 1/02; B32B 27/20; C23C 16/06; B82Y 30/00

(52) U.S. Cl. 428/336; 428/457; 428/426; 428/463; 428/472; 428/472.2; 427/250; 977/773

(57) ABSTRACT

A coated article is provided. The coated article comprises a transparent substrate, a base paint layer directly formed on a surface of the transparent substrate, an aluminum layer directly formed on the aluminum layer, and a top paint layer directly formed on the aluminum layer. The base paint layer is made of a paint containing color paste. The top paint layer is made of a transparent paint. A method for making the coated article is also described.

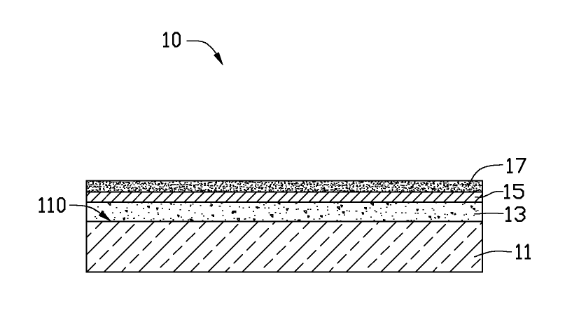

### BACKGROUND

1. Technical Field

The present disclosure relates to coated articles, particularly to a coated article having a good light-proof property and a method for making the coated article.

2. Description of Related Art

Non-conductive vacuum metallization (NCVM) is used for forming metallic coatings having metallic appearance that are non-conductive on electronic devices, such as communication devices. Transparent parts of electronic devices, such as keypads and light-guiding pillars, usually require portions to be light-transmitting while other portions to be coated with metallic coatings must be totally light-proof. However, simple NCVM is difficult to form metallic coatings which are totally light-proof and non-conductive.

Therefore, there is room for improvement within the art.

### BRIEF DESCRIPTION OF THE FIGURE

Many aspects of the disclosure can be better understood with reference to the following figure. The components in the figure are not necessarily drawn to scale, the emphasis instead being placed upon clearly illustrating the principles of the disclosure.

The FIGURE is a cross-sectional view of an exemplary embodiment of a coated article.

### DETAILED DESCRIPTION

The FIGURE shows a portion of a coated article 10 according to an exemplary embodiment. The coated article 10 may be a keypad. The coated article 10 includes a transparent substrate 11, a base paint layer 13 directly formed on a surface 110 of the substrate 11, an aluminum layer 15 directly formed on the base paint layer 13, and a top paint layer 17 directly formed on the aluminum layer 15. As used in this disclosure, “directly” means a surface of one layer is in contact with a surface of the other layer.

The substrate 11 may be made of a transparent material, such as transparent plastic, transparent rubber, or transparent glass. In this exemplary embodiment, the substrate 11 is made of polycarbonate or polymethyl methacrylate.

The base paint layer 13 may be made of a paint mainly comprising acrylic resin. The paint for the base paint layer 13 further contains color paste. The color paste may be either white paste or black paste. In case of white paste, the white paste may have a weight percentage of about 35% to about 40% within the paint. The white paste mainly comprises titanium dioxide particles. In case of black paste, the black paste may have a weight percentage of about 2% to about 4% within the paint. The black paste mainly comprises carbon particles or ferric oxide particles. The color paste may effectively prevent light transmission. The base paint layer 13 may have a thickness of about 10 μm-about 20 μm. The base paint layer 13 may partially cover the surface 110 of the substrate 11.

The thickness of the aluminum layer 15 may be about 200 nm-about 500 nm. When the coated article 10 is used for a communication device (e.g., mobile phone), the aluminum layer 15 within the above thickness range is non-conductive, not interfering with the commutation signals of the communication device. The aluminum layer 15 may entirely cover the base paint coating 13.

The top paint layer 17 may entirely cover the aluminum layer 15. The top paint layer 17 may be made of a transparent paint mainly comprising acrylic resin. The thickness of the top paint layer 17 may be from about 10 μm to about 15 μm.

An exemplary method for making the coated article 10 may include the following steps:

The substrate 11 is provided.

The substrate 11 may be pretreated. The substrate 11 may be cleaned with a solution (e.g., alcohol or acetone) in an ultrasonic cleaner, to remove impurities such as grease or dirt from the substrate 11. Then, the substrate 11 is dried.

The base paint layer 13 is directly formed on a surface 110 of the substrate 11 by spraying a paint mainly comprising acrylic resin. The paint for the base paint layer 13 further contains color paste. The color paste may be either white paste or black paste. In case of white paste, the white paste may have a weight percentage of about 35% to about 40% within the paint for the base paint layer 13. The white paste mainly comprises titanium dioxide. In case of black paste, the black paste may have a weight percentage of about 2% to about 4% within the paint for the base paint layer 13. The black paste mainly comprises carbon or ferric oxide.

The aluminum layer 15 is directly formed on the base paint layer 13 by physical vapor deposition. In this exemplary embodiment, the aluminum layer 15 is formed by vacuum evaporating aluminum at a voltage of about 7 volts (V) to about 9 V and an electric current of about 4000 ampere (A) to about 5000 A. The vacuum evaporating may takes about 7 minutes.

The top paint layer 17 is directly formed on the aluminum layer 15 by spraying a transparent paint mainly comprising acrylic resin.

The light-proof property of the coated article 10 is tested. The test indicates that no light transmits through coated portions of the coated article 10 under the radiation of a LED lamp having a power of 1 W by visual observation. Thus, the coated portions of the coated article 10 have a good light-proof property.

It is believed that the exemplary embodiment and its advantages will be understood from the foregoing description, and it will be apparent that various changes may be made thereto without departing from the spirit and scope of the disclosure or sacrificing all of its advantages, the examples hereinbefore described merely being preferred or exemplary embodiment of the disclosure.

What is claimed is:

1. A coated article, comprising:
a transparent substrate;
a base paint layer directly formed on a surface of the transparent substrate, the base paint layer made of a paint containing color paste;
an aluminum layer directly formed on the aluminum layer; and
a top paint layer directly formed on the aluminum layer, the top paint layer made of a transparent paint.

2. The coated article as claimed in claim 1, wherein the transparent substrate is made of a material selected from the group consisting of transparent plastic, transparent rubber, and transparent glass.

3. The coated article as claimed in claim 1, wherein the paint for the base paint layer mainly comprises acrylic resin.

4. The coated article as claimed in claim 1, wherein the color paste is white paste.

5. The coated article as claimed in claim 4, wherein the white paste has a weight percentage of about 35% to about 40% within the paint for the base paint layer.

6. The coated article as claimed in claim 4, wherein the white paste mainly comprises titanium dioxide particles.

7. The coated article as claimed in claim 1, wherein the color paste is black paste.

8. The coated article as claimed in claim 7, wherein the black paste has a weight percentage of about 2% to about 4% within the paint for the base paint layer.

9. The coated article as claimed in claim 7, wherein the black paste mainly comprises carbon particles.

10. The coated article as claimed in claim 7, wherein the black paste mainly comprises ferric oxide particles.

11. The coated article as claimed in claim 1, wherein the base paint layer has a thickness of about 10 μm-about 20 μm.

12. The coated article as claimed in claim 1, wherein the thickness of the aluminum layer is about 200 nm-about 500 nm.

13. The coated article as claimed in claim 1, wherein the transparent paint for the top paint layer mainly comprises acrylic resin.

14. A method for making a coated article, comprising:
providing a transparent substrate;
forming a base paint layer directly on the substrate spraying a paint containing color paste;
forming an aluminum layer directly on the base paint layer by physical vapor deposition; and
forming a top paint layer directly on the aluminum layer by spraying a transparent paint.

15. The method as claimed in claim 14, wherein the paint for the base paint layer mainly comprises acrylic resin.

16. The method as claimed in claim 14, wherein the color paste is white paste having a weight percentage of about 35% to about 40% within the paint for the base paint layer.

17. The method as claimed in claim 16, wherein the white paste mainly comprises titanium dioxide particles.

18. The method as claimed in claim 14, wherein the color paste is black paste having a weight percentage of about 2% to about 4% within the paint for the base paint layer.

19. The method as claimed in claim 18, wherein the black paste mainly comprises carbon particles or ferric oxide particles.

20. The method as claimed in claim 14, wherein the thickness of the aluminum layer is about 200 nm-about 500 nm.
